(19) United States
(12) Patent Application Publication
(10) Pub. No.: US 2024/0074037 A1
(43) Pub. Date: Feb. 29, 2024

(54) METHOD OF MANUFACTURING ELECTRONIC DEVICE

(71) Applicant: Innolux Corporation, Miaoli County (TW)

(72) Inventors: Yung-Chi Wang, Miaoli County (TW); Ying-Jen Chen, Miaoli County (TW); Chih-Yung Hsieh, Miaoli County (TW)

(73) Assignee: Innolux Corporation, Miaoli County (TW)

(21) Appl. No.: 18/356,189

(22) Filed: Jul. 20, 2023

Related U.S. Application Data
(60) Provisional application No. 63/400,406, filed on Aug. 24, 2022.

(30) Foreign Application Priority Data
Jun. 7, 2023 (CN) 202310668978.4

(51) Int. Cl. H05K 1/02; H05K 3/46

(52) U.S. Cl. CPC H05K 1/024; H05K 3/4688

(57) ABSTRACT

A method of manufacturing an electronic device, including the following steps, is provided. A first dielectric layer and a second dielectric layer are provided. The first dielectric layer has a first surface and a second surface opposite to each other, and the second dielectric layer has a third surface and a fourth surface opposite to each other. A first unit is formed on the first surface or the second surface of the first dielectric layer. The first dielectric layer and the second dielectric layer are combined to form a substrate structure. The second surface of the first dielectric layer faces the third surface of the second dielectric layer. A dielectric loss of the first unit is less than a dielectric loss of the first dielectric layer. The method of manufacturing the electronic device of the embodiment of the disclosure can reduce the dielectric loss by using the unit.

### CROSS-REFERENCE TO RELATED APPLICATION

This application claims the priority benefit of U.S. provisional application Ser. No. 63/400,406, filed on Aug. 24, 2022, and China application serial no. 202310668978.4, filed on Jun. 7, 2023. The entirety of each of the above-mentioned patent applications is hereby incorporated by reference herein and made a part of this specification.

### BACKGROUND

### Technical Field

The disclosure relates to a method of manufacturing an electronic device, and in particular to a method of manufacturing an electronic device which can reduce a dielectric loss by using a unit.

### Description of Related Art

The electronic device or the splicing electronic device has been widely applied to different fields such as communication, display, vehicle, or aviation. With the vigorous development of the electronic device, the electronic device is becoming thinner and lighter, so the requirements for reliability or quality of the electronic device are higher.

### SUMMARY

The disclosure provides a method of manufacturing an electronic device, which can reduce a dielectric loss by using a unit.

According to an embodiment of the disclosure, a method of manufacturing an electronic device includes the following steps. A first dielectric layer and a second dielectric layer are provided. The first dielectric layer has a first surface and a second surface opposite to each other, and the second dielectric layer has a third surface and a fourth surface opposite to each other. A first unit is formed on the first surface or the second surface of the first dielectric layer. The first dielectric layer and the second dielectric layer are combined to form a substrate structure. The step of forming the first unit includes forming a recess on the first surface or the second surface, and a method of forming the recess includes chemical etching, laser drilling, or mechanical frilling.

### BRIEF DESCRIPTION OF THE DRAWINGS

The drawings are included to provide a further understanding of the disclosure, and the drawings are incorporated into the specification and constitute a part of the specification. The drawings illustrate embodiments of the disclosure and serve to explain principles of the disclosure together with the description.

FIG. 1A and FIG. 1B are schematic cross-sectional views of a method of manufacturing an electronic device according to a first embodiment of the disclosure.

FIG. 2 is a schematic cross-sectional view of an electronic device according to a second embodiment of the disclosure.

FIG. 3 is a schematic cross-sectional view of an electronic device according to a third embodiment of the disclosure.

FIG. 4 is a schematic cross-sectional view of an electronic device according to a fourth embodiment of the disclosure.

FIG. 5 is a schematic cross-sectional view of an electronic device according to a fifth embodiment of the disclosure.

FIG. 6 is a schematic cross-sectional view of an electronic device according to a sixth embodiment of the disclosure.

FIG. 7A to FIG. 7B are schematic cross-sectional views of a method of manufacturing an electronic device according to a seventh embodiment of the disclosure.

### DESCRIPTION OF THE EMBODIMENTS

The disclosure may be understood with reference to the following detailed description taken in conjunction with the drawings. It should be noted that for the ease of understanding by the reader and the conciseness of the drawings, multiple drawings of the disclosure only depict a part of an electronic device, and specific elements in the drawings may not be drawn according to actual scale. Furthermore, the number and the size of each element in the drawings are illustrative only and are not intended to limit the scope of the disclosure.

In the following specification and claims, terms such as “containing” and “including” are open-ended terms and should thus be interpreted to mean “comprising but not limited to . . . ”.

It should be understood that when an element or a film layer is referred to as being “on” or “connected to” another element or film layer, the element or film layer may be directly on the other element or film layer or directly connected to the other element or film layer, or there may be an element or a film layer inserted between the two (case of indirect connection). In contrast, when an element or a film layer is referred to as being “directly on” or “directly connected to” another element or film layer, there is no element or film layer inserted between the two.

Although terms such as “first”, “second”, and “third” may be used to describe multiple constituent elements, the constituent elements are not limited by the terms. The terms are only used to distinguish a constituent element from other constituent elements in the specification. The claims may not use the same terms, which may be replaced by first, second, third . . . in the order of declaration of the elements in the claims. Therefore, in the following specification, a first constituent element may be a second constituent element in the claims.

In the text, the terms “about”, “approximately”, “substantially”, and “roughly” usually mean within 10%, 5%, 3%, 2%, 1%, or 0.5% of a given value or range. The number given here is an approximate number, that is, in the case where “about”, “approximately”, “substantially”, and “roughly” are not particularly described, the meanings of “about”, “approximately”, “substantially”, and “roughly” may still be implied.

In some embodiments of the disclosure, terms related to bonding and connection such as “connection” and “interconnection”, unless otherwise specified, may mean that two structures are in direct contact or may also mean that the two structures are not in direct contact, wherein there is another structure disposed between the two structures. Also, the terms related to bonding and connection may also include the case where the two structures are both movable or the two structures are both fixed. In addition, the term “coupling” includes any direct and indirect electrical connection means.

In some embodiments of the disclosure, an optical microscope (OM), a scanning electron microscope (SEM), a thin film thickness profilometer (α-step), an ellipsometer, or other suitable manners may be used to measure the area, the width, the thickness, or the height of each element or the distance or the spacing between elements. In detail, according to some embodiments, the scanning electron microscope may be used to obtain a cross-sectional structure image including the element to be measured and measure the area, the width, the thickness, or the height of each element or the distance or the spacing between elements.

An electronic device of the disclosure may include a display apparatus, an antenna device, a sensing device, or a splicing device, but not limited thereto. The electronic device may be a bendable or flexible electronic device. The electronic device may, for example, include a liquid crystal light emitting diode. The light emitting diode may, for example, include an organic light emitting diode (OLED), a mini LED, a micro LED, or a quantum dot (QD) LED (which may, for example, be QLED or QDLED), fluorescence, phosphor, other suitable materials, or any permutation and combination of the materials, but not limited thereto. The antenna device may, for example, be a phased array antenna, but not limited thereto. The splicing device may, for example, be a display splicing device or an antenna splicing device, but not limited thereto. It should be noted that the electronic device may be any permutation and combination of the above, but not limited thereto. The content of the disclosure will be described below with the electronic device, but the disclosure is not limited thereto.

It should be noted that in the following embodiments, without departing from the spirit of the disclosure, features in several different embodiments may be replaced, reorganized, and mixed to complete other embodiments. As long as the features of the various embodiments do not violate the spirit of the invention or are not conflicting, the features may be arbitrarily mixed and matched for use.

Reference will now be made in detail to the exemplary embodiments of the disclosure, and examples of the exemplary embodiments are illustrated in the drawings. Wherever possible, the same reference numerals are used in the drawings and the description to refer to the same or similar parts.

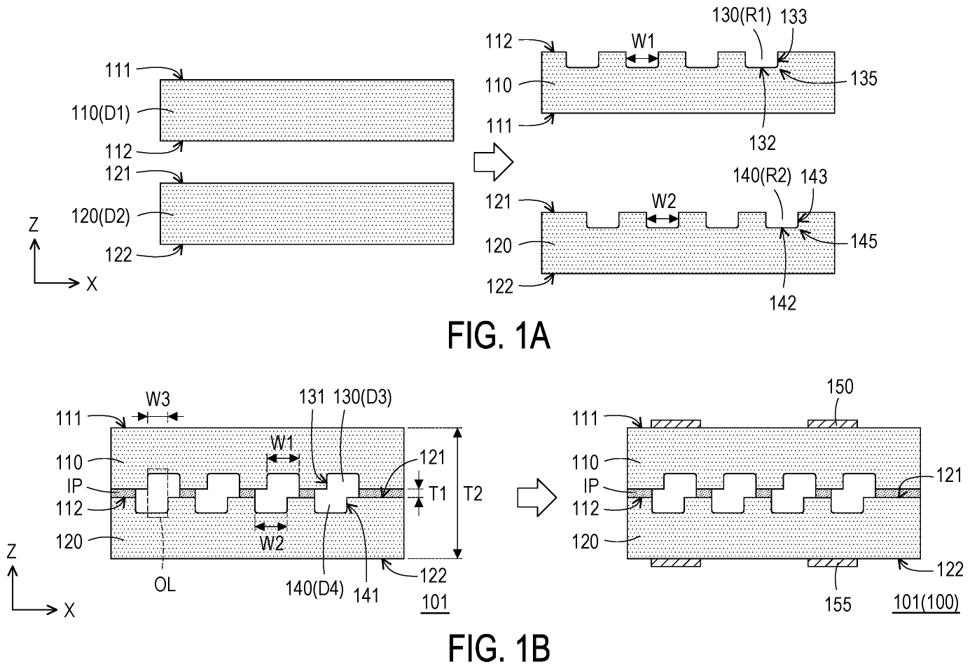

FIG. 1A and FIG. 1B are schematic cross-sectional views of a method of manufacturing an electronic device according to a first embodiment of the disclosure. In the embodiment, the method of manufacturing an electronic device 100 may include the following steps.

Please refer to FIG. 1A. First, a first dielectric layer 110 and a second dielectric layer 120 are provided. The first dielectric layer 110 has a first surface 111 and a second surface 112 opposite to each other, and the second dielectric layer 120 has a third surface 121 and a fourth surface 122 opposite to each other. The first dielectric layer 110 and the second dielectric layer 120 may have a single-layer structure or a multi-layer structure. The materials of the first dielectric layer 110 and the second dielectric layer 120 may include organic materials, inorganic materials, or a combination thereof. For example, the materials of the first dielectric layer 110 and the second dielectric layer 120 may include ceramics, glass, silicon, epoxy, build-up films, other suitable low dielectric materials, or combinations thereof, but not limited thereto. The materials of the first dielectric layer 110 and the second dielectric layer 120 may be the same or different. In the embodiment, the first dielectric layer 110 has a dielectric loss (Df) D1, and the second dielectric layer 120 has a dielectric loss D2.

Then, please continue to refer to FIG. 1A. A first unit 130 is formed on the second surface 112 of the first dielectric layer 110, and a second unit 140 is formed on the third surface 121 of the second dielectric layer 120. Specifically, in the embodiment, the first unit 130 is disposed on the second surface 112 of the first dielectric layer 110, and the first unit 130 may be partially embedded in the second surface 112 of the first dielectric layer 110. The first unit 130 has a bottom surface 132, a side surface 133, and an arc corner 135. The bottom surface 132 may be connected to the side surface 133, and the arc corner 135 may be disposed at a connection between the bottom surface 132 and the side surface 133. For example, it shows that forming the arc corner by a method such as chemical etching, laser drilling, or mechanical frilling may prevent cracking of the electronic device, thereby affecting the electrical quality of the electronic device.

In the embodiment, the second unit 140 is disposed on the third surface 121 of the second dielectric layer 120, and the second unit 140 may be partially embedded in the third surface 121 of the second dielectric layer 120. The second unit 140 has a bottom surface 142, a side surface 143, and an arc corner 145. The bottom surface 142 may be connected to the side surface 143, and the arc corner 145 may be disposed at a connection between the bottom surface 142 and the side surface 143.

In the embodiment, in a direction X, the first unit 130 has a width W1, and the second unit 140 has a width W2. The width W1 is, for example, the maximum width of the first unit 130 measured along the direction X, and the width W2 is, for example, the maximum width of the second unit 140 measured along the direction X. In the embodiment, the direction X and a normal direction Z of the first dielectric layer 110 (or the second dielectric layer 120) are different directions, and the direction X may be roughly perpendicular to the normal direction Z.

In the embodiment, the first unit 130 has a dielectric loss D3, the second unit 140 has a dielectric loss D4, and the dielectric loss D3 of the first unit 130 and the dielectric loss D4 of the second unit 140 are both less than the dielectric loss D1 of the first dielectric layer 110 or the dielectric loss D2 of the second dielectric layer 120. In the embodiment, the dielectric loss D3 of the first unit 130 may be, for example, less than 0.01 (that is, D3<0.01), and the dielectric loss D4 of the second unit 140 may be, for example, less than 0.01 (that is, D4<0.01), but not limited thereto. It shows that reducing the dielectric loss of the substrate material may increase the transmission rate or shorten signal delay, thereby improving the electrical quality of the electronic device, but not limited thereto.

In the embodiment, the steps of forming the first unit 130 on the first dielectric layer 110 and forming the second unit 140 on the second dielectric layer 120 may include the following steps. First, a recess R1 is formed on the second surface 112 of the first dielectric layer 110, and a recess R2 is formed on the third surface 121 of the second dielectric layer 120, wherein a method of forming the recess R1 and the recess R2 may include chemical etching, laser drilling, or mechanical frilling, but not limited thereto. Next, the recess R1, the recess R2, a surface of the first dielectric layer 110, and a surface of the second dielectric layer 120 are cleaned to form the first unit 130 and the second unit 140 which are gas cavities, wherein a method of cleaning may include high-pressure water rinsing, ultraviolet (UV) cleaning, or lotion cleaning, but not limited thereto. For example, the cleaning step may remove organic matter or increase hydrogen bonds on a bonding surface, which can help to improve the bonding quality or reduce the impact of pollutants on the electrical characteristics of the electronic device, but not limited thereto. The bottom surface 132 and the side surface 133 of the first unit 130 may be respectively regarded as a bottom part and a side wall of the recess R1, and the bottom surface 142 and the side surface 143 of the second unit 140 may be respectively regarded as a bottom part and a side wall of the recess R2. Finally, a dielectric material is filled in the recess R1 and the recess R2 to form the first unit 130 and the second unit 140.

In the embodiment, the dielectric materials of the first unit 130 and the second unit 140 may include low dielectric materials having dielectric losses lower than those of the dielectric layers (the first dielectric layer 110 and/or the second dielectric layer 120), such as vacuum, gas, liquid, and solid. For example, the gas may be air, the liquid may be liquid crystal, and the solid may be silicon, but not limited thereto. Therefore, according to the materials used for the first unit 130 and the second unit 140, the first unit 130 and the second unit 140 may be embodied as vacuum cavities, gas cavities, liquid cavities, or solid structures, but not limited thereto.

In some embodiments, if the first unit and the second unit are the vacuum cavities, the steps of forming the first unit in the first dielectric layer and forming the second unit in the second dielectric layer may further include vacuuming the recesses to form the first unit and the second unit which are the vacuum cavities. In some embodiments, if the first unit and the second unit are the liquid cavities, the steps of forming the first unit in the first dielectric layer and forming the second unit in the second dielectric layer may further include filling liquid in the recesses to form the first unit and the second unit which are the liquid cavities. In some embodiments, if the first unit and the second unit are the solid structures, the steps of forming the first unit in the first dielectric layer and forming the second unit in the second dielectric layer may further include filling solid in the recesses to form the first unit and the second unit which are the solid structures.

In the embodiment, although the shapes of the recess R1 (or the first unit 130) and the recess R2 (or the second unit 140) may be roughly rectangular, the disclosure does not limit the shapes of the recesses (or the units). In some unillustrated embodiments, the shapes of the recesses (or the units) may also be arc-shaped.

Then, please refer to FIG. 1B. The first dielectric layer 110 and the second dielectric layer 120 are combined to form a substrate structure 101, so that the second surface 112 of the first dielectric layer 110 may face the third surface 121 of the second dielectric layer 120.

Specifically, in the embodiment, the step of combining the first dielectric layer 110 and the second dielectric layer 120 may include the following steps. First, the first dielectric layer 110 is turned upside down, so that the second surface 112 of the first dielectric layer 110 may face the third surface 121 of the second dielectric layer 120. Next, the first dielectric layer 110 and the second dielectric layer 120 are pressed together by using, for example, high temperature and/or high pressure, so that the first dielectric layer 110 may contact and be combined with the second dielectric layer 120. The high temperature is, for example, greater than or equal to the glass transition temperature (Tg) of the first dielectric layer 110 or the second dielectric layer 120, but not limited thereto.

In some embodiments, the first dielectric layer and the second dielectric layer are pressed together by using high temperature and/or high pressure, so that the first dielectric layer and the second dielectric layer are bonded. For example, the first dielectric layer and the second dielectric layer may be combined by using a high temperature and/or high pressure manner, so that substance interdiffusion occurs at a junction of the first dielectric layer and the second dielectric layer and an interposer IP is formed. The interposer IP combines the first dielectric layer and the second dielectric layer. In some embodiments, in the normal direction Z of the first dielectric layer 110, the interposer IP has a thickness T1, the substrate structure 101 has a thickness T2, and the thickness T1 is greater than 0 and less than or equal to 0.2 times the thickness T2 (0<T1≤0.2×T2). Preferably, the thickness T1 is greater than or equal to 0.05 times the thickness T2 and less than or equal to 0.15 times the thickness T2 (0.05×T2≤T1≤0.15×T2). It shows that the design can improve the combining effect of the dielectric layers, but not limited thereto.

In the embodiment, after combining the first dielectric layer 110 and the second dielectric layer 120 and forming the substrate structure 101, the first unit 130 and the second unit 140 may be disposed between the first dielectric layer 110 and the second dielectric layer 120, so that the first unit 130 may contact the second unit 140, the first unit 130 may overlap with the second unit 140 in the normal direction Z of the first dielectric layer 110, and an overlapping portion OL of the first unit 130 and the second unit 140 may be defined. The overlapping portion OL of the first unit 130 and the second unit 140 in the normal direction Z may have a width W3, and the width W3 is, for example, the maximum width of the overlapping portion OL measured from the side 131 of the first unit 130 to a side 141 of the second unit 140 along the direction X, wherein the side 131 of the first unit 130 is adjacent to the side 141 of the second unit 140.

In the embodiment, when the first unit 130 may partially overlap with the second unit 140 in the normal direction Z of the first dielectric layer 110, the width W3 of the overlapping portion OL may be, for example, greater than or equal to ⅓ times the width W1 of the first unit 130 (or the width W2 of the second unit 140) and less than the width W1 of the first unit 130 (or the width W2 of the second unit 140) (that is, ⅓×W1≤W3<W1 or ⅓×W2≤W3<W2), but not limited thereto. In some embodiments, when the second unit may completely overlap with the first unit in the normal direction of the first dielectric layer, the width of the overlapping portion may be, for example, equal to the width of the first unit (or the width of the second unit).

Then, please continue to refer to FIG. 1B. A first metal layer 150 is disposed on the first surface 111 of the first dielectric layer 110 in the substrate structure 101, and the second metal layer 155 is disposed on the fourth surface 122 of the second dielectric layer 120 in the substrate structure 101. In the embodiment, the first metal layer 150 and the second metal layer 155 may be patterned metal layers. The first metal layer 150 may expose a part of the first surface 111 of the first dielectric layer 110, and the second metal layer 155 may expose a part of the fourth surface 122 of the second dielectric layer 120. So far, the manufacturing of the electronic device 100 of the embodiment may be roughly completed.

In the embodiment, the electronic device 100 may be applied to an antenna device, but not limited thereto. The first metal layer 150 and the second metal layer 155 disposed on two sides of the substrate structure 101 may be used for signal transmission, and the dielectric loss of the substrate structure 101 affects the speed and the quality of signal transmission between the first metal layer 150 and the second metal layer 155. However, compared to a conventional electronic device in which a single-layer dielectric layer (for example, polyester (PES) or polytetrafluoroethylene (PTFE) mixed with ceramics) which is expensive and has a low dielectric loss is used as a substrate structure, the electronic device 100 of the embodiment obtains the substrate structure 101 with a low dielectric loss by using the design manner of at least two layers of dielectric layers (that is, the first dielectric layer 110 and the second dielectric layer 120) in conjunction with units (that is, the first unit 130 and/or the second unit 140), so as to reduce the manufacturing cost and achieve the effects of shortening signal delay, increasing signal transmission rate, or reducing signal transmission loss.

In addition, in the electronic device 100 of the embodiment, it shows that adjusting the width W3 of the overlapping portion OL of the first unit 130 and the second unit 140 changes the dielectric loss of the substrate structure 101 to increase the adjustability of the dielectric loss and satisfy different application requirements.

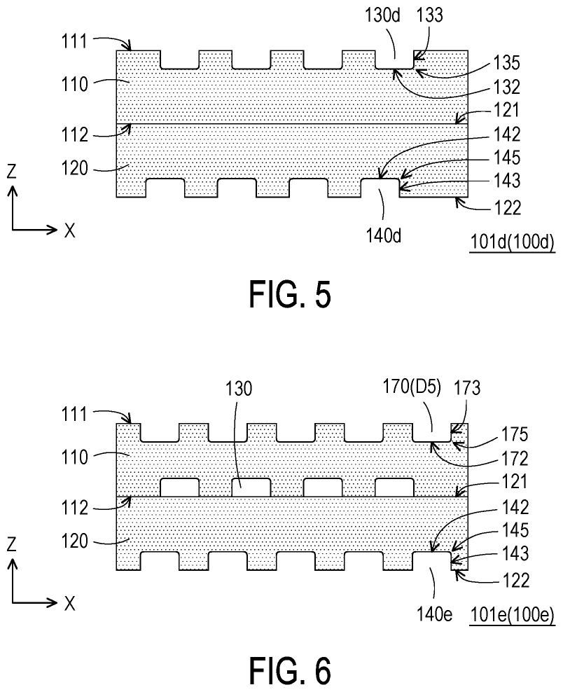

Although the substrate structure 101 of the electronic device 100 of the embodiment has two layers of dielectric layers (that is, the first dielectric layer 110 and the second dielectric layer 120) and two layers of units (that is, the first unit 130 and the second unit 140), and the two layers of units are both disposed between the first dielectric layer 110 and the second dielectric layer 120, the disclosure does not limit the number of layers of the dielectric layers, the number of layers of the units, and the positions of the units in the substrate structure 101. In other words, in some embodiments, the substrate structure may also have one layer of units, as shown in FIG. 3 and FIG. 4. In some embodiments, the substrate structure may also have three layers of units, as shown in FIG. 6. In some embodiments, the units in the substrate structure may not be disposed between the first dielectric layer and the second dielectric layer, as shown in FIG. 4, FIG. 5, and FIG. 6. In some unillustrated embodiments, the substrate structure may also have three or more layers of dielectric layers. In some unillustrated embodiments, the substrate structure may also have four or more layers of units.

Other embodiments are listed below for illustration. It must be noted here that the following embodiments continue to use the reference numerals and some content of the foregoing embodiment, wherein the same reference numerals are used to represent the same or similar elements, and the description of the same technical contents is omitted. For the description of the omitted part, reference may be made to the foregoing embodiment, which will not be repeated in the following embodiments.

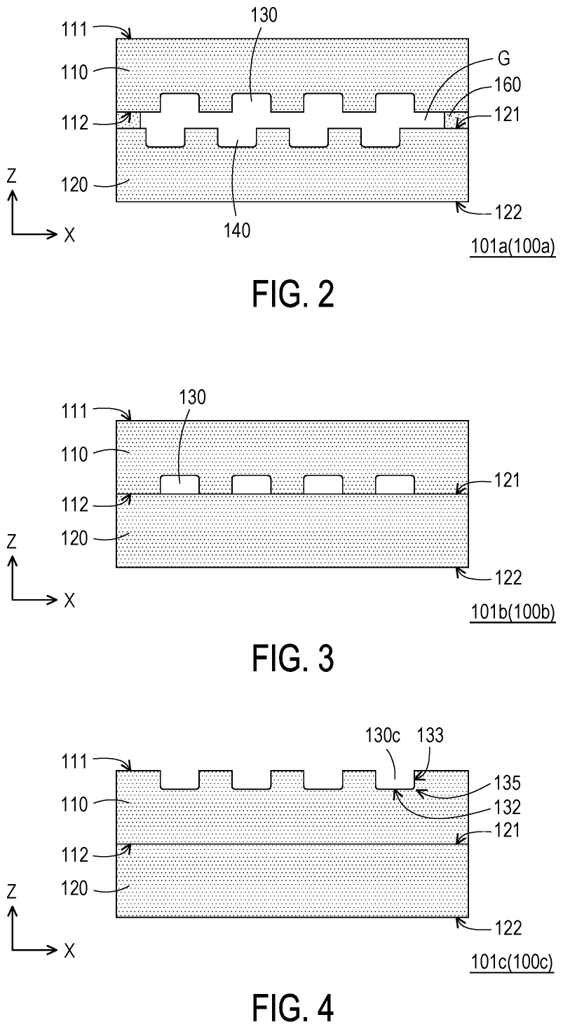

FIG. 2 is a schematic cross-sectional view of an electronic device according to a second embodiment of the disclosure. For clarity of the drawings and convenience of illustration, the first metal layer and the second metal layer in the electronic device are omitted in FIG. 2. Please refer to FIG. 1B and FIG. 2 at the same time. An electronic device 100a of the embodiment is similar to the electronic device 100 of FIG. 1B, but the differences between the two are that the electronic device 100a of the embodiment further includes an adhesive 160 and a gap G, and the first dielectric layer 110 does not contact the second dielectric layer 120.

Specifically, please refer to FIG. 2. In the embodiment, the adhesive 160 is disposed between the second surface 112 of the first dielectric layer 110 and the third surface 121 of the second dielectric layer 120 in a substrate structure 101a. The adhesive 160 may be used as a sealant to bond the first dielectric layer 110 and the second dielectric layer 120. In the embodiment, the adhesive 160 may, for example, be UV glue, thermosetting glue, or other suitable adhesive materials, but not limited thereto.

In the embodiment, the gap G may be disposed between the second surface 112 of the first dielectric layer 110 and the third surface 121 of the second dielectric layer 120, and the gap G may be surrounded by the adhesive 160. The gap G may also be disposed between the first unit 130 and the second unit 140, and the gap G may connect the first unit 130 and the second unit 140.

Different from the method of manufacturing the electronic device 100 of FIG. 1A and FIG. 1B, in a method of manufacturing the electronic device 100a of the embodiment, a method of combining the first dielectric layer 110 and the second dielectric layer 120 may include the following steps. First, the adhesive 160 is coated on a frame of the second surface 112 of the first dielectric layer 110 or the third surface 121 of the second dielectric layer 120 by using, for example, a one drop filling (ODF) method. Next, the first dielectric layer 110 and the second dielectric layer 120 are connected by using the adhesive 160, so that the first dielectric layer 110 may be bonded to the second dielectric layer 120 by the adhesive 160.

FIG. 3 is a schematic cross-sectional view of an electronic device according to a third embodiment of the disclosure. For clarity of the drawings and convenience of illustration, the first metal layer and the second metal layer in the electronic device are omitted in FIG. 3. Please refer to FIG. 1B and FIG. 3 at the same time. An electronic device 100b of the embodiment is similar to the electronic device 100 of FIG. 1B, but the difference between the two is that the second unit is not disposed on the second dielectric layer 120a in a substrate structure 101b of the electronic device 100b of the embodiment.

FIG. 4 is a schematic cross-sectional view of an electronic device according to a fourth embodiment of the disclosure. For clarity of the drawings and convenience of illustration, the first metal layer and the second metal layer in the electronic device are omitted in FIG. 4. Please refer to FIG. 1B and FIG. 4 at the same time. An electronic device 100c of the embodiment is similar to the electronic device 100 of FIG. 1B, but the difference between the two is that a first unit 130c in a substrate structure 101c is not disposed between the first dielectric layer 110 and the second dielectric layer 120. In addition, the second unit is not disposed in the substrate structure 101c of the electronic device 100c of the embodiment.

Specifically, please refer to FIG. 4. In the embodiment, the first unit 130c is disposed on the first surface 111 of the first dielectric layer 110, and the first unit 130c may be partially embedded in the first surface 111 of the first dielectric layer 110.

FIG. 5 is a schematic cross-sectional view of an electronic device according to a fifth embodiment of the disclosure. For clarity of the drawings and convenience of illustration, the first metal layer and the second metal layer in the electronic device are omitted in FIG. 5. Please refer to FIG. 1B and FIG. 5 at the same time. An electronic device 100d of the embodiment is similar to the electronic device 100 of FIG. 1B, but the difference between the two is that in the electronic device 100d of the embodiment, a first unit 130d and a second unit 140d in a substrate structure 101d are not disposed between the first dielectric layer 110 and the second dielectric layer 120.

Specifically, please refer to FIG. 5. In the embodiment, the first unit 130d is disposed on the first surface 111 of the first dielectric layer 110, and the first unit 130d may be partially embedded in the first surface 111 of the first dielectric layer 110. The second unit 140d is disposed on the fourth surface 122 of the second dielectric layer 120, and the second unit 140d may be partially embedded in the fourth surface 122 of the second dielectric layer 120. In the embodiment, the first unit 130d may overlap with the second unit 140d in the normal direction Z of the first dielectric layer 110.

FIG. 6 is a schematic cross-sectional view of an electronic device according to a sixth embodiment of the disclosure. For clarity of the drawings and convenience of illustration, the first metal layer and the second metal layer in the electronic device are omitted in FIG. 6. Please refer to FIG. 1B and FIG. 6 at the same time. An electronic device 100e of the embodiment is similar to the electronic device 100 of FIG. 1B, but the difference between the two is that in the electronic device 100e of the embodiment, a second unit 140e in a substrate structure 101e is not disposed between the first dielectric layer 110 and the second dielectric layer 120. In addition, the electronic device 100e of the embodiment further includes a third unit 170.

Specifically, please refer to FIG. 6. In the embodiment, the second unit 140e is disposed on the fourth surface 122 of the second dielectric layer 120, and the second unit 140e may be partially embedded in the fourth surface 122 of the second dielectric layer 120.

In the embodiment, the third unit 170 is disposed on the first surface 111 of the first dielectric layer 110, and the third unit 170 may be partially embedded in the first surface 111 of the first dielectric layer 110. The third unit 170 has a bottom surface 172, a side surface 173, and an arc corner 175. The bottom surface 172 may be connected to the side surface 173, and the arc corner 175 may be disposed at a connection between the bottom surface 172 and the side surface 173.

In the embodiment, the third unit 170 has a dielectric loss D5, and the dielectric loss D5 of the third unit 170 is less than the dielectric loss D1 of the first dielectric layer 110 or the dielectric loss D2 of the second dielectric layer 120. In the embodiment, the dielectric loss D5 of the third unit 170 may be, for example, less than 0.01 (that is, D5<0.01), but not limited thereto.

In the embodiment, the third unit 170 may overlap with the first unit 130 and the second unit 140e in the normal direction Z of the first dielectric layer 110, and the first unit 130 may overlap with the second unit 140e in the normal direction Z of the first dielectric layer 110.

Different from the method of manufacturing the electronic device 100 of FIG. 1A and FIG. 1B, a method of manufacturing the electronic device 100e of the embodiment may further include forming the third unit 170 on the first surface 111 of the first dielectric layer 110, so that the third unit 170 may overlap with the first unit 130 in the normal direction Z of the first dielectric layer 110.

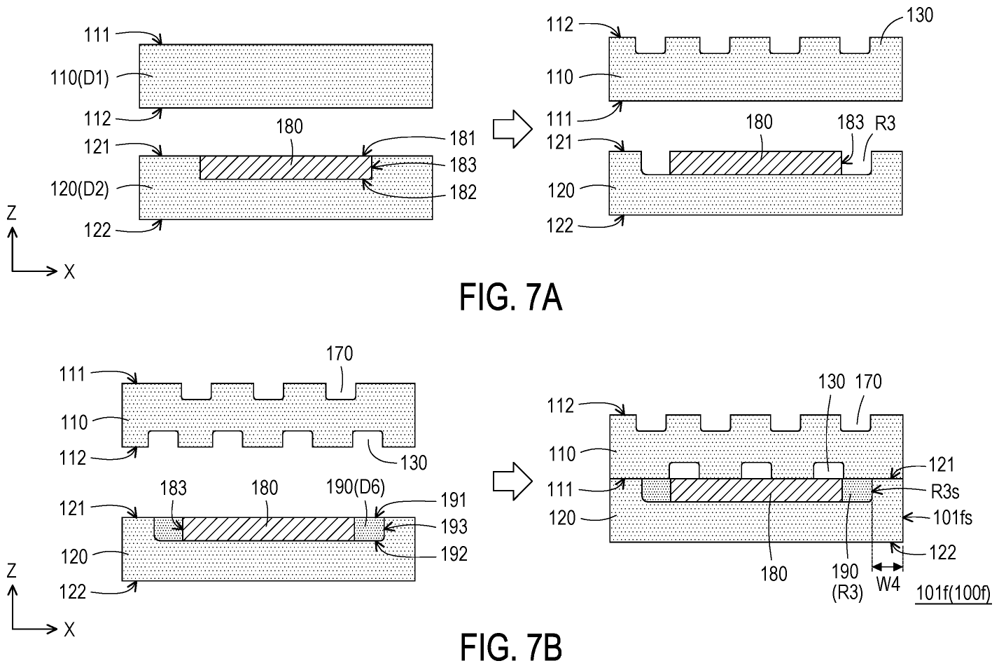

FIG. 7A to FIG. 7B are schematic cross-sectional views of a method of manufacturing an electronic device according to a seventh embodiment of the disclosure. For clarity of the drawings and convenience of illustration, the first metal layer and the second metal layer in the electronic device are omitted in FIG. 7B. The embodiment shown in FIG. 7A to FIG. 7B is similar to the embodiment shown in FIG. 1A and FIG. 1B, so the same elements or similar components may adopt the same materials or methods. Therefore, the same or similar description for the two embodiments will not be repeated in the following, and the differences between the two embodiments will be mainly explained. In the embodiment, a method of manufacturing an electronic device 100f may include the following steps.

Please refer to FIG. 7A. First, the first dielectric layer 110 and the second dielectric layer 120 are provided, and a third metal layer 180 is disposed on the third surface 121 of the second dielectric layer 120, so that the third metal layer 180 is partially embedded in the second dielectric layer 120. Specifically, in the embodiment, the third metal layer 180 has an upper surface 181, a lower surface 182, and a side surface 183. The upper surface 181 and the lower surface 182 are opposite to each other, the upper surface 181 is farther away from the fourth surface 122 of the second dielectric layer 120 than the lower surface 182, and the upper surface 181 may be exposed outside the second dielectric layer 120. The upper surface 181 may be roughly aligned with the third surface 121 of the second dielectric layer 120, but not limited thereto. The side surface 183 connects the upper surface 181 and the lower surface 182.

Then, please continue to refer to FIG. 7A. The first unit 130 is formed on the second surface 112 of the first dielectric layer 110, and a recess R3 is formed on the third surface 121 of the second dielectric layer 120, so that the recess R3 exposes the side surface 183 of the third metal layer 180. In the embodiment, a method of forming the recess R3 may include chemical etching, laser drilling, or mechanical frilling, but not limited thereto.

Then, please refer to FIG. 7B. The third unit 170 is formed on the first surface 111 of the first dielectric layer 110, and a dielectric material layer 190 is formed in the recess R3. Specifically, in the embodiment, the third unit 170 may overlap with the first unit 130 in the normal direction Z of the first dielectric layer 110.

In the embodiment, the dielectric material layer 190 is disposed on the third surface 121 of the second dielectric layer 120, and the dielectric material layer 190 may be partially embedded in the third surface 121 of the second dielectric layer 120. The dielectric material layer 190 has an upper surface 191, a lower surface 192, and a side surface 193. The upper surface 191 and the lower surface 192 are opposite to each other, the upper surface 191 is farther away from the fourth surface 122 of the second dielectric layer 120 than the lower surface 192, and the upper surface 191 may be exposed outside the second dielectric layer 120. The upper surface 191 may be roughly aligned with the third surface 121 of the second dielectric layer 120, but not limited thereto. The side surface 193 connects the upper surface 191 and the lower surface 192. The dielectric material layer 190 may contact the side surface 183 of the third metal layer 180.

In the embodiment, the dielectric material layer 190 has a dielectric loss D6, and the dielectric loss D6 of the dielectric material layer 190 is less than the dielectric loss D1 of the first dielectric layer 110 or the dielectric loss D2 of the second dielectric layer 120. In the embodiment, the dielectric loss D6 of the dielectric material layer 190 may be, for example, less than 0.01 (that is, D6<0.01), but not limited thereto. In addition, in the embodiment, the material of the dielectric material layer 190 may include a solid low dielectric material. For example, the material of the dielectric material layer 190 may include a silicon-containing low dielectric material, such as siloxane, but not limited thereto.

Then, please continue to refer to FIG. 7B. The first dielectric layer 110 and the second dielectric layer 120 are combined to form a substrate structure 101f, so that the second surface 112 of the first dielectric layer 110 may face the third surface 121 of the second dielectric layer 120.

In the embodiment, after combining the first dielectric layer 110 and the second dielectric layer 120, the first unit 130, the third metal layer 180, and the dielectric material layer 190 may be disposed between the first dielectric layer 110 and the second dielectric layer 120, so that the first unit 130 may contact the third metal layer 180, and the first unit 130 may overlap with the third metal layer 180 in the normal direction Z of the first dielectric layer 110. So far, the manufacturing of the electronic device 100f of the embodiment may be roughly completed. According to some embodiments, there is a width W4 between a side 101fs of the substrate structure 101f and a side R3s of the recess R3. The width W4 is, for example, the maximum width measured between the side R3s and the side 101fs along the direction X. In other words, the width of a junction of the first dielectric layer 110 and the second dielectric layer 120 is W4. In detail, the width W4 is greater than or equal to 1 centimeter (cm) and less than or equal to 10 cm. It shows that the design can improve the adhesion between the dielectric layers to prevent foreign objects or pollutants from penetrating and affecting electrical properties or reliability. In other words, a ratio of the width of the junction to the width of the dielectric layer being greater than or equal to 10% or less than or equal to 30% can improve the adhesion between the dielectric layers, wherein the width of the junction is the sum of the widths of the junctions on two sides in a schematic cross-sectional view.

In the embodiment, it shows that disposing the third metal layer 180 between the first dielectric layer 110 and the second dielectric layer 120 can be used to improve the quality of signal transmission.

In some unillustrated embodiments, the third metal layer and the dielectric material layer may also be disposed on the third surface of the second dielectric layer according to requirements.

In summary, in the method of manufacturing the electronic device of the embodiment of the disclosure, the substrate structure with a low dielectric loss is obtained by using the design manner of at least two layers of dielectric layers (that is, the first dielectric layer and the second dielectric layer) in conjunction with units (that is, the first unit and/or the second unit), so as to reduce the manufacturing cost and achieve the effects of shortening signal delay, increasing signal transmission rate, or reducing signal transmission loss. In addition, it shows that adjusting the width of the overlapping portion of the first unit and the second unit may be used to change the dielectric loss of the substrate structure, so as to increase the adjustability of the dielectric loss and satisfy different application requirements. In addition, it shows that disposing the third metal layer between the first dielectric layer and the second dielectric layer may be used to improve the quality of signal transmission.

Finally, it should be noted that the above embodiments are only used to illustrate, but not to limit, the technical solutions of the disclosure. Although the disclosure has been described in detail with reference to the above embodiments, persons skilled in the art should understand that the technical solutions described in the above embodiments may still be modified or some or all of the technical features thereof may be equivalently replaced. However, the modifications or replacements do not cause the essence of the corresponding technical solutions to deviate from the scope of the technical solutions of the embodiments of the disclosure.

What is claimed is:

1. A method of manufacturing an electronic device, comprising:
providing a first dielectric layer and a second dielectric layer, wherein the first dielectric layer has a first surface and a second surface opposite to each other, and the second dielectric layer has a third surface and a fourth surface opposite to each other;
forming a first unit on the first surface or the second surface of the first dielectric layer; and
combining the first dielectric layer and the second dielectric layer to form a substrate structure, wherein the second surface of the first dielectric layer faces the third surface of the second dielectric layer,
wherein the step of forming the first unit on the first dielectric layer comprises forming a recess on the first surface or the second surface of the first dielectric layer, and a method of forming the recess comprises chemical etching, laser drilling, or mechanical frilling.

2. The method of manufacturing according to claim 1, wherein a dielectric loss of the first unit is less than a dielectric loss of the first dielectric layer.

3. The method of manufacturing according to claim 2, wherein a dielectric loss of the first unit is less than 0.01.

4. The method of manufacturing according to claim 1, wherein the first unit has an arc corner.

5. The method of manufacturing according to claim 1, wherein the step of combining the first dielectric layer and the second dielectric layer comprises:
pressing the first dielectric layer and the second dielectric layer together, so that the first dielectric layer contacts the second dielectric layer.

6. The method of manufacturing according to claim 1, wherein the method of combining the first dielectric layer and the second dielectric layer comprises:
disposing an adhesive on the second surface of the first dielectric layer; and
connecting the first dielectric layer and the second dielectric layer by using the adhesive.

7. The method of manufacturing according to claim 1, further comprising:
forming a second unit on the third surface or the fourth surface of the second dielectric layer, so that the second unit overlaps with the first unit.

8. The method of manufacturing according to claim 7, wherein a width of an overlapping portion of the first unit and the second unit is greater than or equal to ⅓ times a width of the first unit and less than or equal to the width of the first unit.

9. The method of manufacturing according to claim 7, wherein the second unit is disposed between the second surface of the first dielectric layer and the third surface of the second dielectric layer.

10. The method of manufacturing according to claim 7, wherein the second unit is disposed on the fourth surface of the second dielectric layer.

11. The method of manufacturing according to claim 1, further comprising:
disposing a first metal layer on the first surface of the first dielectric layer in the substrate structure; and
disposing a second metal layer on the fourth surface of the second dielectric layer in the substrate structure.

12. The method of manufacturing according to claim 11, further comprising:
disposing a third metal layer on the third surface of the second dielectric layer, so that the third metal layer is embedded in the second dielectric layer,
wherein the third metal layer has an upper surface, a lower surface, and a side surface, and the upper surface is exposed outside the second dielectric layer.

13. The method of manufacturing according to claim 12, wherein the third metal layer overlaps with the first unit.

14. The method of manufacturing according to claim 12, further comprising:
forming another recess on the third surface of the second dielectric layer, so that the another recess exposes the side surface of the third metal layer; and
forming a dielectric material layer in the another recess, wherein a dielectric loss of the dielectric material layer is less than the dielectric loss of the first dielectric layer.

15. The method of manufacturing according to claim 14, wherein the dielectric loss of the dielectric material layer is less than 0.01.

16. The method of manufacturing according to claim 1, wherein the first unit is a gas cavity or a vacuum cavity.

17. The method of manufacturing according to claim 1, wherein a material of the first unit is gas, liquid, or solid.

18. The method of manufacturing according to claim 1, wherein the first unit is disposed between the first dielectric layer and the second dielectric layer.

19. The method of manufacturing according to claim 1, wherein the first unit is disposed on the first surface of the first dielectric layer.

20. The method of manufacturing according to claim 1, wherein the first unit is disposed on the second surface of the first dielectric layer, and the method of manufacturing further comprises:
forming a third unit on the first surface of the first dielectric layer, so that the third unit overlaps with the first unit.
